(19) United States
(12) Patent Application Publication
(10) Pub. No.: US 2024/0330081 A1
(43) Pub. Date: Oct. 3, 2024

(54) APPARATUS INCLUDING PERFORMANCE COUNTER MECHANISM AND ASSOCIATED METHODS

(71) Applicant: Micron Technology, Inc., Boise, ID (US)

(72) Inventors: Chikara Kondo, Tokyo (JP); Nathaniel J. Meier, Boise, ID (US); Tomoki Hayashi, Chofu (JP); Roman A. Royer, Boise, ID (US); Sean K. Moss, Boise, ID (US); Stewart R. Watson, Boise, ID (US)

(21) Appl. No.: 18/605,006

(22) Filed: Mar. 14, 2024

Related U.S. Application Data
(60) Provisional application No. 63/456,401, filed on Mar. 31, 2023.

(51) Int. Cl. G06F 9/54

(52) U.S. Cl. CPC G06F 9/542

(57) ABSTRACT

An apparatus including a selectable event reporter internal to a memory device and associated systems and methods are disclosed herein. In some embodiments, the selectable event reporter is dynamically configured to load user-defined event parameters. The selectable event reporter uses the user-defined event parameters to detect corresponding states in command and address signals provided by an external processor. The selectable event reporter communicates the detected events and/or other related observations to an external device.

### CROSS-REFERENCE TO RELATED APPLICATION(S)

The present application claims priority to U.S. Provisional Patent Application No. 63/456,401, filed Mar. 31, 2023, the disclosure of which is incorporated herein by reference in its entirety.

### TECHNICAL FIELD

The present technology is directed to apparatuses, such as semiconductor devices including memory and processors, and several embodiments are directed to semiconductor devices that include performance counter mechanisms.

### BACKGROUND

An apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high bandwidth memory (HBM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing operating speeds or otherwise reducing operational latency, increasing reliability, increasing data retention, reducing power consumption, or reducing manufacturing costs, among other metrics. However, attempts to meet the market demands, such as by reducing the overall device footprint, can often introduce challenges in other aspects, such as for maintaining circuit robustness and/or failure detectability.

### BRIEF DESCRIPTION OF THE DRAWINGS

FIG. 1 is a cross-sectional view of a system-in-package device in accordance with embodiments of the technology.

FIG. 2 is a block diagram of a memory device in accordance with embodiments of the technology.

FIG. 3 is a block diagram of a first portion of the memory device of FIG. 2 in accordance with embodiments of the technology.

FIG. 4 is a block diagram of a second portion of the memory device of FIG. 2 in accordance with embodiments of the technology.

FIG. 5 is a block diagram of a third portion of the memory device of FIG. 2 in accordance with embodiments of the technology.

FIG. 6 is a block diagram of a fourth portion of the memory device of FIG. 2 in accordance with embodiments of the technology.

FIG. 7 is a block diagram of a fifth portion of the memory device of FIG. 2 in accordance with embodiments of the technology.

FIG. 8 is a flow diagram illustrating an example method of manufacturing an apparatus in accordance with an embodiment of the present technology.

FIG. 9 is a block diagram of a system that includes an apparatus configured in accordance with embodiments of the present technology.

### DETAILED DESCRIPTION

As described in greater detail below, the technology disclosed herein relates to an apparatus, such as for memory systems, systems with memory devices, related methods, etc., for providing details regarding internal operations. An apparatus (e.g., a memory device, such as an HBM and/or a DRAM, and/or a corresponding system) can local include a selectable event reporter configurable to detect one or more of multiple event indicators. For example, the selectable event reporter can be configured according to an operator (e.g., a test conductor, an external device, or the like) to detect timings of one or more selected signal conditions. The selectable event reporter can provide the captured timings of the selected signal conditions to the operator. Some examples of the selectable signal conditions can be according to channels, banks, targeted commands, or the like as observed within the apparatus. Moreover, the selectable event reporter can be configured with custom or user-defined trigger (e.g., auto stop threshold/condition).

Conventional computing systems typically include a processor and a memory. The processor includes a counter that is tied to a fixed signal and controlled based on a start command and a stop command. Additionally, in conventional system-in-package (SiP) computing systems (e.g., HBMs), some internal signals may be inaccessible to external systems. Moreover, for some signals, connection to a measurement device or a corresponding connection may introduce changes to the measured signal.

In contrast, embodiments of the present technology include the selectable event reporter within the SiP, such as within a memory subsystem, that can be customized to detect and report user-specified conditions. The selectable event reporter can utilize existing connection (e.g., P1500) for both specifying the signal/condition targeted for observation and providing the measured results. Accordingly, the selectable event reporter can provide the required measurements/observations without additional external hardware or logic analyzers. The selectable event reporter can provide debugging and event-capture features to circuits outside of the processor. Moreover, the selectable event reporter can be configured in real-time or according to context, thereby providing device-specific insight and debugging features. The selectable event reporter can allow for debugging of system failures beyond pass/fail results, obtain detailed descriptions of memory activity of different benchmarks (e.g., read operations, write operations, refresh operations, etc.). For example, the selectable event reporter can determine whether internal operations meet or violate timing requirements.

### Example Environment

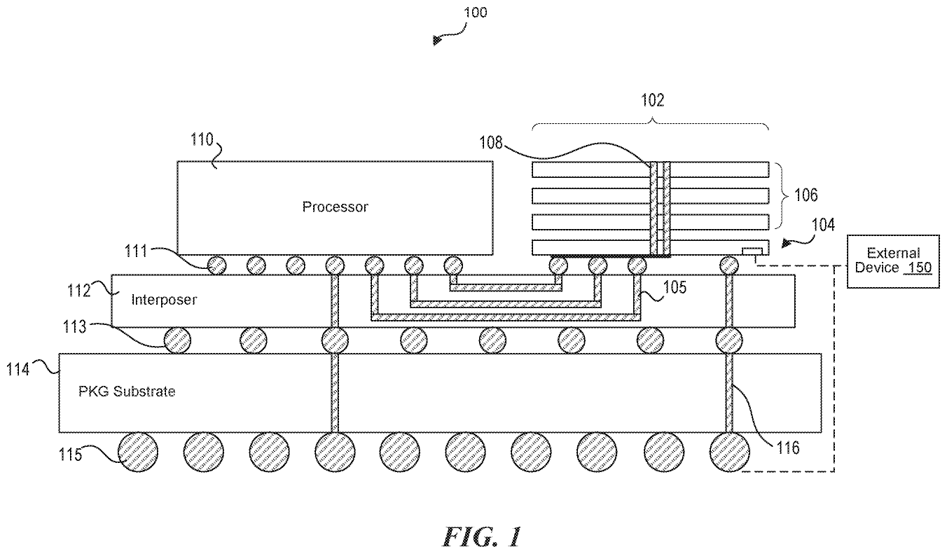

FIG. 1 illustrates a schematic cross-sectional view of a SiP device 100 (i.e., an example apparatus) in accordance with embodiments of the technology. The SiP 100 can include the memory device 102 and the processor 110, which are packaged together on a package substrate 114 along with an interposer 112. The processor 110 may act as a host device of the SiP 100.

In some embodiments, the memory device 102 may be an HBM device that includes an interface die (or logic die) 104 and one or more memory core dies 106 stacked on the interface die 104. The memory device 102 can include one or more through silicon vias (TSVs) 108, which may be used to couple the interface die 104 and the core dies 106.

The interposer 112 can provide electrical connections between the processor 110, the memory device 102, and/or the package substrate 114. For example, the processor 110 and the memory device 102 may both be coupled to the interposer 112 by a number of internal connectors (e.g., micro-bumps 111). The interposer 112 may include channels 105 (e.g., an interfacing or a connecting circuit) that electrically couple the processor 110 and the memory device 102 through the corresponding micro-bumps 111. Although only three channels 105 are shown in FIG. 1, greater or fewer numbers of channels 105 may be used. The interposer 112 may be coupled to the package substrate by one or more additional connections (e.g., intermediate bumps 113, such as C4 bumps).

The package substrate 114 can provide an external interface for the SiP 100. The package substrate 114 can include external bumps 115, some of which may be coupled to the processor 110, the memory device 102, or both. The package substrate 114 may further include direct access (DA) bumps coupled through the package substrate 114 and interposer 112 to the interface die 104.

In some embodiments, the direct access bumps 116 (e.g., one or more of the bumps 115) and/or other bumps may be organized into a probe pad (e.g., a set of test connectors). An external device 150, such as a tester, may be coupled onto the probe pad in order to directly communicate with the memory device 102. In other words, the external device 150 may send signals to and/or receive signals from the memory device 102 without the signals passing through the processor 110 after the memory device 102 is mounted on the interposer 112.

In one or more embodiments, the external device 150 may be used to test and debug the memory device 102 after it is mounted on the interposer 112 and/or coupled to the processor 110. For example, the external device 150 can be used to determine one or more aspects of implementing memory operations, such as in response to commands provided by the processor 110. The memory device 102 can use a selectable event reporter that is configurable (via, e.g., the external device 150) in real-time to determine and report the one or more aspects of the implemented memory operations. The selectable event reporter may be included in the interface die 104. Details regarding the interface die 104 and the selectable event reporter are described below.

### Example Circuitry

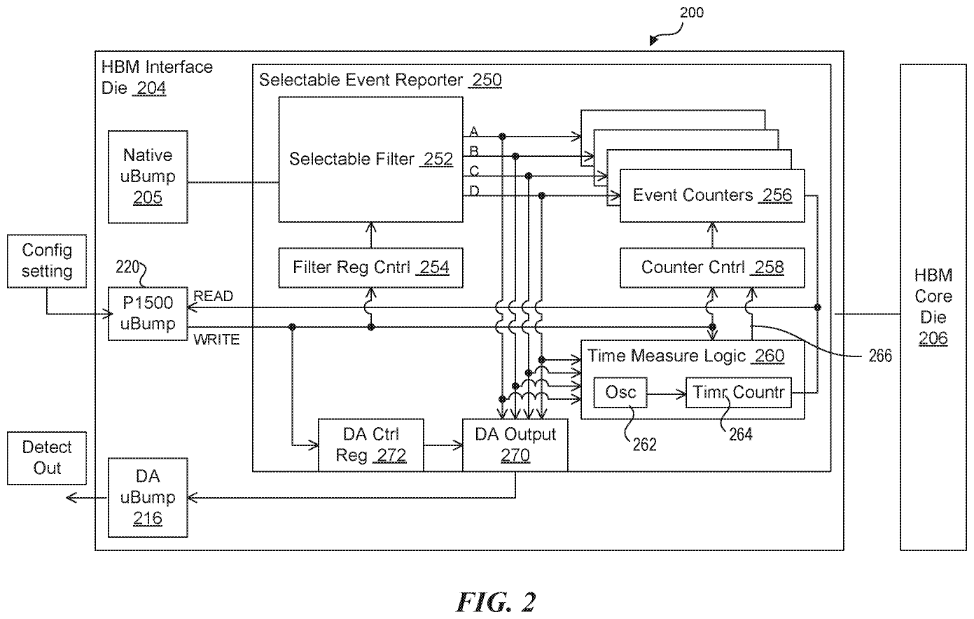

FIG. 2 is a block diagram of a memory device 200 (i.e., an example apparatus, such as the memory device 102 of FIG. 1 or a portion thereof) in accordance with embodiments of the technology. The memory device 200 may include an interface die 204 (e.g., an instance of of the logic die 104 of FIG. 1) and one or more core dies 206 (e.g., one or more instances of the memory core dies 106 of FIG. 1). For clarity, only a single core die 206 is shown in FIG. 2, however it should be understood that multiple core dies 206 may be coupled to the interface die 204 (e.g., there may be 1, 2, or a greater number of core dies 206).

The memory device 200 can include different interface terminals for accessing the core dic(s) 206 and/or one or more circuits of the memory. In some embodiments, the different interface terminals can include native micro-bumps (uBumps) 205, DA uBumps 216, and/or test interface uBumps 220. The test interface uBumps 220 may be part of a specific interface protocol, such as the IEEE 1500 interface (also referred to as a P1500 interface). The native uBumps 205 may, in some embodiments, be included in the uBumps 111 of FIG. 1. The native uBumps 205 may be coupled to a processor (e.g., the processor 110 of FIG. 1) via one or more connections (e.g., the channels 105 of FIG. 1). The native uBumps 205 and the connections can enable the processor to access information (via, e.g., read or write operations and the corresponding exchange of information) in the core die(s) 206. For example, the core dies 206 may receive a command (e.g., a read command) along with address information (AWORD), such as such as a row address, column address, a bank address, a die identifier, or the like, that specifies a location for the memory access. The AWORD may also include command information, such as clock signals used for the timing of operations and command identifiers. The accessed information (DWORD), such as the write data or the read data can also be exchanged through the native uBumps 205.

Internally, the uBumps 205 can be coupled to the core die(s) 206 through a command bus having a set of channels (e.g., 16 channels). For example, the command bus can communicate a row command and address signal (e.g., R[9:0]), a column command and address signal (e.g., C[7:0]), a clock signal (e.g., CK), or a combination thereof. The clock signal may include a set of coordinated signals, such as a complementary set of signals including a target clock signal (CK_t) and a complementary clock signal (CK_c).

In some embodiments, the interface die 204 may include a selectable event reporter 250 coupled between the native uBumps 205 and the storage circuits (e.g., memory arrays, including those in the core die(s) 206). The selectable event reporter 250 can be configurable in real-time (e.g., post die or memory device 200 manufacturing) to detect one or more of dynamically selected event indicators. For example, the selectable event reporter 250 can be configured according to an operator (e.g., a test conductor, the external device 150 of FIG. 150, or the like) to detect timings of one or more selected signal conditions. The selectable event reporter can provide the captured timings of the selected signal conditions to the operator. Some examples of the selectable signal conditions can be according to channels, banks, targeted commands, or the like as observed within the apparatus. Moreover, the selectable event reporter 250 can be configured with custom or user-defined trigger (e.g., auto stop threshold/condition).

The selectable event reporter 250 can include a selectable filter 252 that can be configured in real-time to issue an event signal when an input on the command bus matches a targeted condition. For example, the selectable filter 252 can include configurable logic, multiplexer, digital filters, or the like that may be dynamically programmed and/or selected to load one or more programmed thresholds and/or comparison operators (e.g., equal to, less than, greater than, or the like). The selectable filter 252 can use the loaded thresholds and/or operators to compare against the incoming command signals. When the comparison satisfies the programmed condition as defined by the thresholds and/or the comparison operators, the selectable filter 252 can output an event match signal. As illustrated in FIG. 2, the selectable event reporter 250 can concurrently monitor four event conditions labeled A, B, C, and D. However, it is understood that the selectable event reporter 250 can be configured to monitor any number of conditions (e.g., two or greater).

In some embodiments, the selectable filter 252 can be preloaded with selection parameters, such as channels, banks, commands, and/or similar settings that can be controlled or provided by the processor 110 of FIG. 1. The external device 150 and/or the end user can select a set of parameters, corresponding thresholds, and/or operators to effectively define the events targeted for detection. Additionally or alternatively, the selectable filter 252 can include a predetermined set of events and corresponding parameters, thresholds, and/or operators. The end user and/or the external device 150 can select one or more events as detection targets.

As illustrative example, the selectable filter 252 can be configured to set a trigger start and trigger stop signal to measure internal specification timings through the use of an on-die clock circuit (described below), such as for time active to precharge (tRAS), time precharge (tRP), minimum burst duration (tCCD), time refresh interval (tREFI), and the like. Also, the selectable filter 252 can be configured to set a trigger start and trigger stop signal to count events over specific intervals in a pattern or type of operation, such as a first RFM to a second RFM command. In other words, the selectable filter 252 can count the number of acts that can occur to a bank. Additionally, the selectable filter 252 can be configured to implement an auto stop count to record the time it takes to record/detect a threshold number of events.

The interface die 204 can receive the user selection information through one or more of the interfaces. For example, the interface die 204 can interact with the external device 150 through the P1500 uBump 220 to obtain the parameters or the corresponding trigger settings. The information can be received and stored at a filter register controller 254. The filter register controller 254 can provide the selected configuration settings for the selectable filter 252.

The selectable event reporter 250 can further include a set of event counters 256 that increment based on the event signal (e.g., indications of event detection) provided by the selectable filter 252. Each of the event counters 256 can be coupled or assigned to each event. The event counters 256 can be coupled to a counter controller 258 that is configured to control operations of the event counters 256. For example, the counter controller 258 can receive user settings (via, e.g., the P1500 uBump 220) for controlling counter thresholds, counter resetting functions, increment directions, initial counter value, or the like.

Additionally, the selectable event reporter 250 can include a timing measurement logic 260 configured to control timing measurements. The timing measurement logic 260 can include a timing circuit, such as an internal oscillator 262 and a timer counter 264. The internal oscillator 262 can generate a predetermined frequency that can be used as a timing reference. The timer counter 264 can be configured to measure the time, such as by counting the oscillations in the output from the internal oscillator 262. In some embodiments, the timer counter 264 can generate timestamps that can be provided to the event counters 256. Moreover, the timer counter 264 can provide a timer control signal 266 for controlling start and/or stop operations for the event counters 256. The event counter 256 can respond to the event detection signal from the selectable filter 252 and generate the timestamp, which can be stored at the corresponding one of the event counters 256. The timing measurement logic 260 may be configured according to the externally provided settings to detect the auto-start and auto-stop conditions.

The selectable event reporter 250 can provide the detection outputs to the end user and/or the external device 150 through one or more of the interfaces described above. For example, the selectable event reporter 250 can provide the detection outputs through a DA output circuit 270, which can be controlled by a DA control register 272. The DA control register 272 can receive the output command through the P1500 uBump 220 and enable/disable the DA output circuit 270 accordingly. When activated, the DA output circuit 270 can communicate the values/data stored in the event counters 256 through the DA uBump 216. Also, the output circuit 270 can communicate the detection outputs from the selectable filter 252 through the DA uBump 216. Additionally or alternatively, the selectable event reporter 250 can provide the counter values through the P1500 uBump 220.

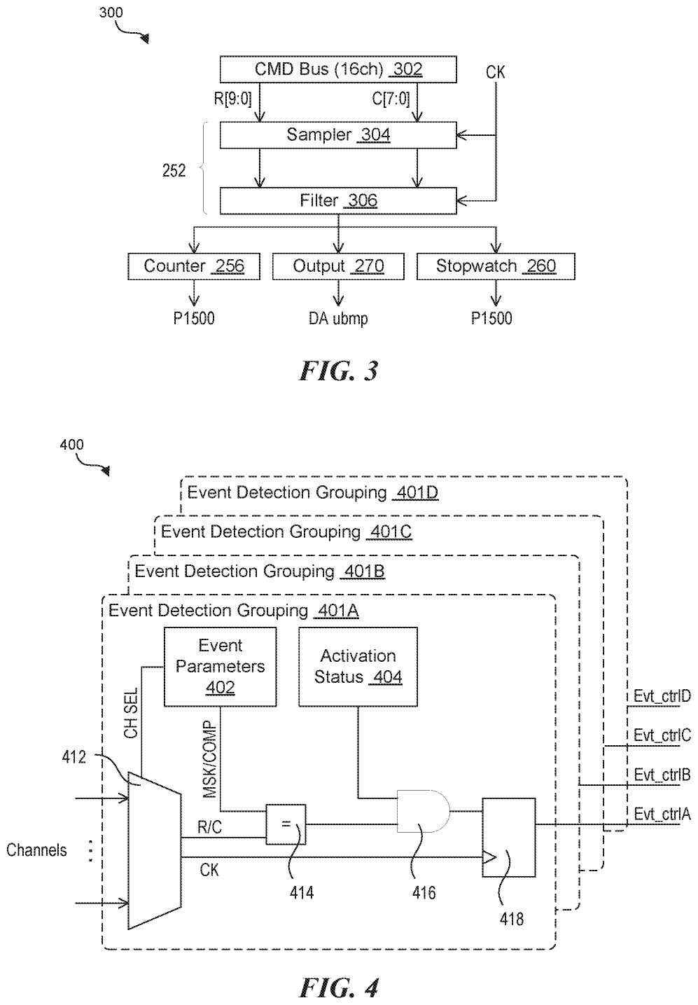

FIG. 3 is a block diagram of a first portion 300 of the memory device 200 of FIG. 2 in accordance with embodiments of the technology. The first portion 300 can include the selectable filter 252 having connectors interfacing with a command bus 302 and providing its output to the event counters 256, the DA output circuit 270, the timing measurement logic 260 (e.g., stopwatch), or a combination thereof.

The command bus 302 can provide the row command and address signal (e.g., R[9:0]), a column command and address signal (e.g., C[7:0]), a clock signal (e.g., CK), or a combination thereof to the selectable filter 252. The illustrated example in FIG. 3 shows a 16-channel command bus. However, it is understood that the command bus can have more or less channels.

In some embodiments, the selectable filter 252 can include a sampler 304 and a filter 306. The sampler 304 can be configured to capture the row and column commands according to the clock signal. The filter 306 can compare the captured commands to the specified/selected event parameters. The filter 306 can generate the event signal when the captured command matches the event parameters as described above.

The event signal from the filter 306 can be received at the counter 256, the DA output circuit 270, and/or the timing measurement logic 260. The counter 256 can increment and count the number of detected events as described above. Also, as described above, the DA output circuit 270 can communicate the output (e.g., the counter value and/or the event signal through the DA uBump 216. In some embodiments, the timing measurement logic 260 can be configured to count the number of cycles (e.g., measure a duration) between selected commands based on the event signal. In other words, the timing measurement logic 260 can measure a duration separating adjacent instances of the same command or two different commands as specified in the event parameters. The outputs from the counter 256 and the timing measurement logic 260 can be communicated out through the P1500 uBump 220.

FIG. 4 is a block diagram of a second portion 400 of the memory device 200 of FIG. 2 in accordance with embodiments of the technology. The second portion 400 can illustrate an example design for the filter 306 of FIG. 3. In some embodiments, the filter 306 can be implemented using multiple event detection circuit groupings 401 (e.g., circuit groupings or modules 401A-401D). Each circuit grouping 401 can be configured and operated independently using the controller 254 of FIG. 2 to observe and detect targeted events as described above. The circuit groupings 401 can be arranged parallel to each other and be communicatively coupled to the channels in the command bus 302 of FIG. 3.

Each of the circuit groupings 401 can include registers or storage circuits configured to store event parameters 402 and activation status 404. The event parameters 402 and the activation status 404 can include information provided by the external device 150 of FIG. 1 to describe or define the targeted event for the corresponding circuit grouping. For example, the event parameters 402 can identify a targeted/selected channel, one or more bit masks, one or more comparison bit values, or a combination thereof that defines the targeted event.

In some embodiments, each of the circuit groupings 401 can process the event parameters 402 and the activation status 404 using a multiplexer 412, a comparator 414, an activation circuit 416, and an output driver 418. For example, the multiplexer 412 can allow the selected channel as identified in the event parameters 402 to pass to the comparator 414 while blocking other channels. The comparator 414 can receive the bit-wise representation of the targeted event and compare such representation to the row/column commands and addresses received on the selected channel. The comparator 414 can provide an indication when the compared values match, and the activation circuit 416 (e.g., an AND gate) can provide the match indication downstream when the activation status 404 indicates active event detection status for the circuit grouping. The output driver 418 (e.g., a flipflop) can provide the match indication as an event detection output (EvtA-EvtD or Evt_ctrlA-Evt_ctrlD) to downstream circuits as described above according to a system clock signal CK.

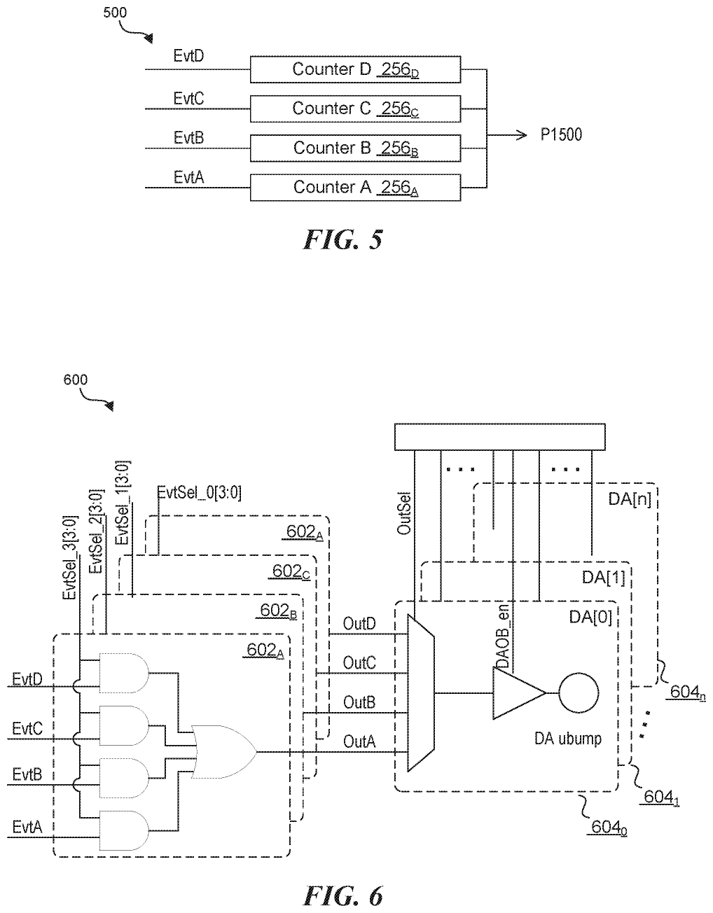

One of the circuits receiving the event detection signal is illustrated in FIG. 5 as a block diagram of a third portion 500 of the memory device 200 of FIG. 2 in accordance with embodiments of the technology. The third portion 500 can correspond to the event counters 256 of FIG. 2. For example, the event counters 256 can include counter A 256_{A}-counter D 256_{D} that are each connected to a corresponding one of the circuit groupings and events A-D. Accordingly, each counter can count the number of corresponding target event. The counters may be read as one or more chains via the P1500 communication path.

Another one of the circuits receiving the event detection signal is illustrated in FIG. 6 as a block diagram of a fourth portion 600 of the memory device 200 of FIG. 2 in accordance with embodiments of the technology. The fourth portion 600 can correspond to the DA output circuit 270 of FIG. 2. Similar to the filters and counters described above, the DA output circuit 270 can include a matching number of receiving circuit groupings that are each dedicated to one or more of the event signals. In other words, the DA output circuit 270 can have a number of receiving circuit groupings (e.g., groupings 602_{A}-602_{D}) that match a maximum number of simultaneously detectable events.

Each of the receiving circuit grouping 602 can receive the full set of event signal outputs (e.g., EvtA-EvtD). Moreover, each grouping can receive an event selection signal (e.g., one of EvtSel_0-EvtSel_3) that identifies, for the corresponding circuit grouping 602, the one or more event signals to output through the DA uBump. For example, each bit in the event selection signal can represent a communication status of a corresponding event signal. Accordingly, the bits within the event selection can be combined (via, e.g., AND gates) to allow the activated event signal to pass through to a combining component (e.g., an OR gate) that generates a combined output signal (e.g., one of OutA-OutD) for each circuit grouping 602.

The combined outputs can be communicated to DA driver circuit groupings (e.g., groupings 604₀-604ₙ) that each correspond to a bit for a DA output or a corresponding DA uBump. In other words, the DA output circuit can have n+1 number of driver groupings, one for each bit in the output DA word.

Each in the driver circuit grouping can include a multiplexer that receives the combined outputs (e.g., signals OutA-OutD) from the receiving circuit groupings 602. The multiplexer can selectively convey one or more of the received combined outputs according to an output selection (OutSel). The selected output signal can be provided to a driver that further amplifies and provides power to convey the output signal to the corresponding DA uBump. The driver can communicate the DA output according to an enable signal (DAOB_en).

The DA output signal can be processed according to the various selection and enable signals described above. The DA output circuit 270 can receive such selection and enable signals/settings from the DA control register 272 of FIG. 2, which may be configured via the P1500 interface as described above.

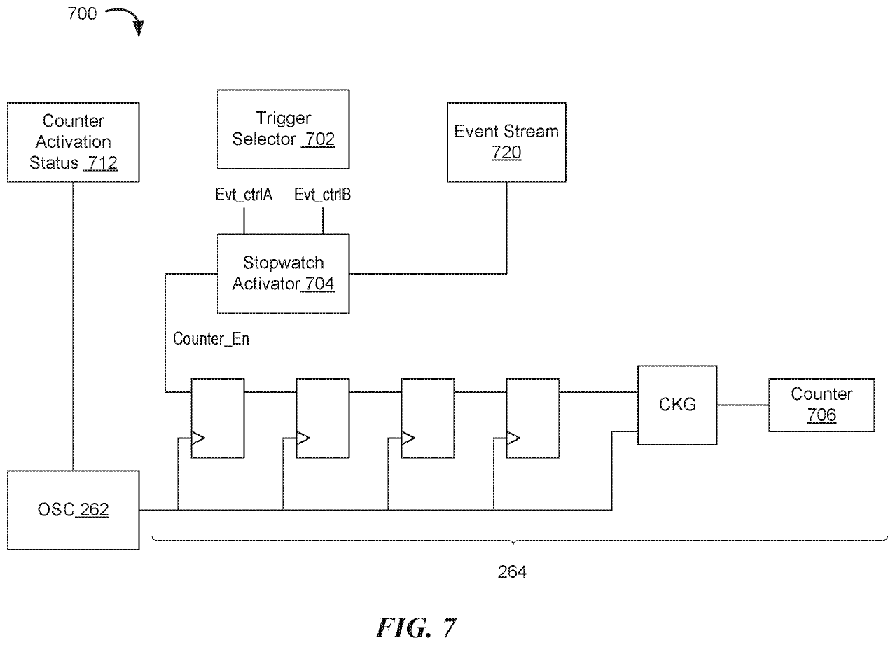

FIG. 7 is a block diagram of a fifth portion 700 of the memory device 200 of FIG. 2 in accordance with embodiments of the technology. The fifth portion 700 can correspond to the timing measurement logic 260 of FIG. 2. The timing measurement logic 260 can include the internal oscillator 262 and the timer counter 264 as described above. In some embodiments, the internal oscillator can be controlled (e.g., activated or deactivated) using a counter activation status 712. The counter activation status 712 can be provided via the P1500 interface. When activated, the internal oscillator 262 can provide a reference signal having a known or a measurable frequency. In some embodiments, the timing measurement logic 260 can leverage externally provided references (e.g., reference signal injected through the DA interface, the CK signal, or the like) for the timing measurement. The periods of the reference signal can be counted to measure the duration that lapsed between a measurement start event and a measurement stop event.

To identify the measurement start and stop events, the timing measurement logic 260 can include a trigger selector 702 configured to selectively route one or more event detection signals (e.g., Evt_cntrlA-Evt_cntrlD) to a stopwatch activator 704. The trigger selector 702 can route the signals according to the measurement setting, which may be communicated via the P1500 interface as described above. The trigger selector 702 can further configure the stopwatch activator 704 to start and stop the measurements based on the same event or for different events. Accordingly, the trigger selector 702 can configure the stopwatch activator 704 to create the measurement start and stop events that measure a separation between (1) two adjacent occurrences of the same event signal or (2) a first event signal and a second event signal.

The stopwatch activator 704 can be configured to control the status of a counter enable signal (Counter_En) that is used to identify a duration between occurrences of watched events. For example, the stopwatch activator 704 can analyze an event stream 720 (e.g., real-time states of the event signals) according to the configuration settings provided by the trigger selector 702. When the event stream 720 includes a signal state (indicating an event occurrence) that matches the measurement start condition, the stopwatch activator 704 can provide the counter enable signal to a set of flip flips that toggle according to the output of the internal oscillator 262 and provide an output to a clock gate. The timing measurement logic 260 can include a counter 706 that increments according to the oscillating signal provided by the clock gate when the counter enable signal indicates that the measurement start event has occurred and until the counter enable signal transitions to indicate that the measurement start event has occurred.

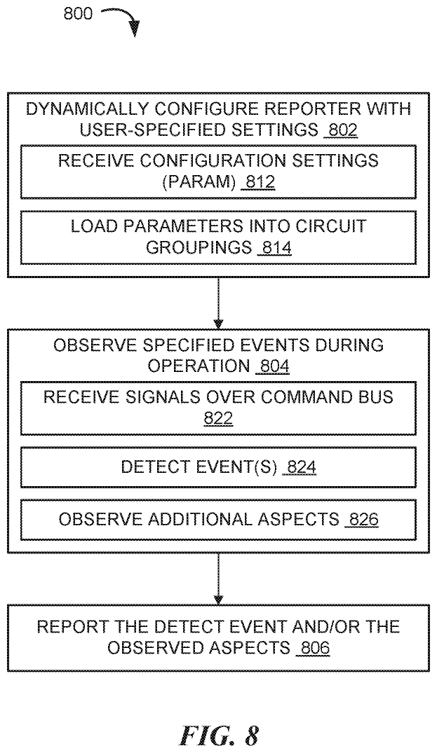

FIG. 8 is a flow diagram illustrating an example method 800 of operating an apparatus (e.g., the SiP 100 of FIG. 1, the memory device 102 of FIG. 1, the memory device 200 of FIG. 2, the interface die 104/204, the selectable event reporter 250 of FIG. 2, or a combination thereof) in accordance with an embodiment of the present technology. The method 800 can be for dynamically configuring the selectable event reporter 250 to (1) detect one or more user-defined events and/or (2) make related measurements, and (3) communicate the detected events, the measurements, or a combination thereof. The method 800 can correspond to observing and reporting one or more user-specified aspects of operations internal to the memory device 102/200.

At block 802, the memory device can dynamically configure an on-board event reporter (e.g., the selectable event reporter 250) with user-specified settings. For example, at block 812, the memory device can receive configurations/parameters or corresponding signal states that represent user-designated events as described above, such as through the P1500 interface. The processor 110 of FIG. 1, the external device 150 of FIG. 1, or both can be used to provide the configurations/parameters. At block 814, the parameters can be locally stored at one or more of the circuits groupings within the event reporter. For example, the user-provided parameters can be stored at one or more of the filters, output circuit, counters, time measurement logic, or the like as described above for local comparison or processing.

At block 804, the memory device can observe specified events during operation. The memory device can use the event reporter to observe the specified events while executing commands provided by the processor 110 and/or while executing internally originated operations (e.g., refresh operations). For example, at block 822, the memory device can receive signals (e.g., memory operation commands) over the command bus. The received signals can be analyzed at the filters as described above to detect events that match the user specified event parameters as shown in block 824. The filters can independently perform the analysis to detect the designated events. Upon detecting the event, the corresponding filter can generate an event detection signal to notify the detected event.

The detection signal can be conveyed to other circuit groupings for further observations as illustrated in block 826. For example, the event counters 256 of FIG. 2 can be used to count the transitions in or occurrences of the event signal. Also, the timing measurement logic 260 can measure durations related to the detected event. The timing measurements can automatically start and stop according to the same command or using different commands as start and stop markers. In some embodiments, the combination of observations can be used to perform a task. For example, the duration can be measured until the counter reaches a threshold number. Also, the reporter may trigger an action, such as to deactivate the filter, control the timer, initiate a report output, or the like based on the counter reaching a threshold number.

At block 806, the memory device can report the detected event(s) and/or the observed aspects to an external device, such as the processor 110 and/or the external device 150. For example, the memory device can use the DA output circuit 270 and/or the P1500 interface to send the event detection signal or a derivation thereof (e.g., the related observations, such as counts, durations, etc.) as described above.

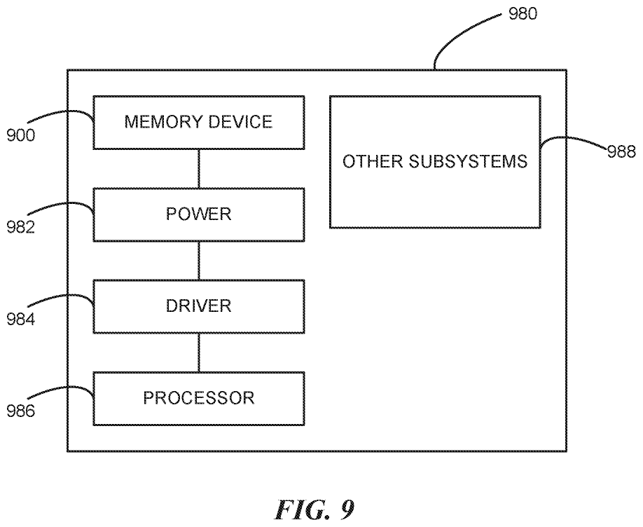

FIG. 9 is a block diagram of a system that includes an apparatus in accordance with embodiments of the present technology. Any one of the foregoing apparatuses (e.g., memory devices) described above with reference to FIGS. 1-8 can be incorporated into or implemented in memory (e.g., a memory device 900) or any of a myriad of larger and/or more complex systems, a representative example of which is system 980 shown schematically in FIG. 9. The system 980 can include the memory device 900, a power source 982, a driver 984, a processor 986, and/or other subsystems or components 988. The memory device 900 can include features generally similar to those of the apparatus described above with reference to FIGS. 1-8 and can therefore include various features for performing a direct read request from a host device. The resulting system 980 can perform any of a wide variety of functions, such as memory storage, data processing, and/or other suitable functions. Accordingly, representative systems 980 can include, without limitation, hand-held devices (e.g., mobile phones, tablets, digital readers, and digital audio players), computers, vehicles, appliances and other products. Components of the system 980 may be housed in a single unit or distributed over multiple, interconnected units (e.g., through a communications network). The components of the system 980 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of HBM and DRAM devices. Apparatuses configured in accordance with other embodiments of the present technology, however, can include other types of suitable storage media in addition to or in lieu of HBM and/or DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structures includes information arranged as bits, words or code-words, blocks, files, input data, system generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-9.

What is claimed is:

1. A memory device, comprising:
at least one storage die configured to store data therein; and
an interface die coupled to the at least one storage die and configured to facilitate interactions between the at least one storage die and a combination of a processor and an external device, wherein the interface die includes:
a command bus connector configured to receive command and address signals provided by the processor for storing the data to or accessing the stored data or from the interface die, the at least one storage die, or a combination thereof;
a selectable event reporter coupled to the command bus connector and configured to:
dynamically receive event parameters from the processor and/or the external device, wherein the configuration parameters represent a user-identified event targeted for measurement or detection during operation of the memory device;
generate an event detection signal that indicates a detection of the user-identified event based on comparing the event parameters to the command and address signals; and
communicate the event detection signal or a derivation thereof for reporting the detection of the user-identified event or a related measurement to the external device.

2. The memory device of claim 1, wherein:
the selectable event reporter includes at least a first event detection circuit and a second event detection circuit that are each (1) coupled to the command bus connector and (2) configured to independently detect an event occurring with respect to the command and address signals as dynamically identified by the user; and
a user selected one of the first and second event detection circuits is configured according to the event parameters to generate the event detection signal.

3. The memory device of claim 2, wherein:
the command bus connector is configured to couple each of the first and second event detection circuits to two or more channels;
each of the first and second event detection circuits includes:
a local storage for storing parameters that define the event for detection, wherein the parameters identify a targeted channel; and
a multiplexer coupled to the command bus connector and configured to isolate the targeted channel for an event detection analysis.

4. The memory device of claim 3, wherein:
the locally stored parameters further define a state for one or more signals for representing the event; and
each of the first and second event detection circuits are further configured to perform the event detection analysis by:
comparing the one or more signals on the targeted channel to the locally stored parameters; and
generating an event signal when the one or more signals matches the state defined by the locally stored parameters, wherein the event signal generated by the user selected one of the first and second event detection circuits comprises the event detection signal.

5. The memory device of claim 2, wherein the selectable event reporter further comprises a timing measurement logic having an internal oscillator, the timing measurement logic configured to measure a duration relative to the event detection signal.

6. The memory device of claim 5, wherein:
the first event detection circuit is configured to generate a first event signal based on detecting a first event condition; and
the second event detection circuit is configured to generate a second event signal based on detecting a first event condition, wherein the first and second event conditions are different; and
the timing measurement logic is configured to measure a duration between the first and second event signals.

7. The memory device of claim 5, wherein the timing measurement logic is configured to measure a duration between transitions in the event detection signal.

8. The memory device of claim 2, wherein the selectable event reporter includes at least:
a first counter coupled to the first event detection circuit and configured to count transitions in a first event signal generated by the first event detection circuit; and
a second counter coupled to the second event detection circuit and configured to count transitions in a second event signal generated by the second event detection circuit, wherein the reported derivation of the event detection signal includes the counted transitions for the first event signal, the second event signal, or both.

9. The memory device of claim 1, wherein the interface die further comprises:
a P1500 interface configured to receive the event parameters, communicate the event detection signal or the derivation thereof, or both.

10. The memory device of claim 9, further comprising:
a direct access (DA) interface configured to communicate the event detection signal or the derivation thereof, or both.

11. The memory device of claim 1, wherein the at least one storage die and the interface die are stacked and comprise a high bandwidth memory (HBM) configured for usage in a system in package (SiP).

12. A method of operating a memory device, the method comprising:
at the memory device, receiving command and address signals from an external processor, wherein the command and address signals are for storing data on the memory device, accessing the data stored on the memory device, or internally processing the data stored at the memory device;
at the memory device, receiving event parameters from the external processor and/or an external test device, wherein the configuration parameters describe a state of the command and address signals that represent a user-identified event targeted for observation during operation of the memory device;
generating an event detection signal that indicates an occurrence of the user-identified event based on comparing the event parameters to the command and address signals; and
communicating the event detection signal or a derivation thereof externally from the memory device for reporting the detection of the user-identified event or a related measurement to the external device.

13. The method of claim 12, further comprising:
using multiple selectable filters in the memory device, observing the command address signals for multiple user-identified events, wherein the generated event detection signal indicates the occurrence of one of the multiple user-identified events.

14. The method of claim 13, wherein generating the event detection signal includes:
storing the event parameters locally at one of the multiple selectable filters;
using the one of the multiple selectable filters to compare the locally stored event parameters with the command and address signals; and
generating the event detection signal from the one of the multiple selectable filters when the event parameters match the state of the command and address signals.

15. The method of claim 14, further comprising:
using a second of the multiple selectable filters, generating a second event signal when the command and address signals has a second state matching locally stored parameters representative of a second user-defined event that is different from the user-identified event; and
measuring a duration between the second event signal and the event detection signal, wherein the communicated derivation of the event detection signal includes the measured duration between two different events.

16. The method of claim 12, further comprising:
counting transitions in the event detection signal, wherein the communicated derivation of the event detection signal includes the counted transitions.

17. The method of claim 16, wherein:
the event parameters include an automatic stop threshold;
stopping the detection and the event detection signal generation when the counted transitions reach the automatic stop threshold; and
further comprising:
measuring a duration between a first generation of the event detection signal and satisfaction of the automatic stop threshold.

18. The method of claim 12, wherein:
the event parameters are received over a P1500 interface; and
the event detection signal or the derivation thereof is communicated over a direct access (DA) interface, the P1500 interface, or a combination thereof.

19. A computing device including a high bandwidth memory (HBM), comprising:
one or more storage dies configured to store data therein; and
a semiconductor die disposed under and coupled to the one or more storage dies, wherein the interface die is configured to facilitate interactions between the one or more storage dies and includes:
a command bus connector configured to receive command and address signals provided by a processor for storing the data to or accessing the stored data or from the interface die, the one or more storage dies, or a combination thereof;
a selectable event reporter coupled to the command bus connector and configured to:
dynamically receive event parameters from the processor and/or an external device, wherein the configuration parameters represent a user-identified event targeted for measurement or detection during operation of the memory device;
generate an event detection signal that indicates a detection of the user-identified event based on comparing the event parameters to the command and address signals; and
communicate the event detection signal or a derivation thereof for reporting the detection of the user-identified event or a related measurement to the external device.

20. The computing device of claim 19, further comprising:
a processor;
an interposer having the processor and the HBM mounted thereon,
wherein the HBM includes the one or more storage dies and the interface die stacked on top of each other, and
wherein the processor, the HBM, and the interposer comprise a system in package (SiP).
